(19) United States
(12) Patent Application Publication
(10) Pub. No.: US 2010/0224393 A1
(43) Pub. Date: Sep. 9, 2010

(54) Display device

(75) Inventors: Kenta Kamoshida, Tokorozawa (JP); Hideshi Nomura, Togane (JP); Yasuko Gotoh, Mobara (JP)

Correspondence Address: Juan Carlos A. Marquez;c/o Stites & Harbison PLLC, 1199 North Fairfax Street, Suite 900, Alexandria, VA, 22314-1437, US

(73) Assignee: Hitachi Displays, Ltd.

(21) Appl. No.: 12/659,455

(22) Filed: Mar. 9, 2010

Related U.S. Application Data
(63) Continuation of application No. 11/329,243, filed on Jan. 11, 2006, now abandoned.

(30) Foreign Application Priority Data
Jan. 12, 2005 (JP) 2005-005393

(51) Int. Cl. H05K 1/00

(52) U.S. Cl. 174/250

(57) ABSTRACT

A display device with signal lines formed on a substrate and an organic insulation film which covers the signal lines and is formed over an upper layer side of the substrate, the display device further includes a terminal portion on which a conductive film is formed in a state that the conductive film covers portions of the signal lines which are exposed through openings formed in the organic insulation film, wherein the organic insulation film sets a film thickness thereof at a periphery of the terminal portion smaller than the film thickness at other portions, and a surface of small-film-thickness portion arranged in peripheries of the openings is formed into an uneven surface.

### CROSS-REFERENCE TO RELATED APPLICATION

This application is a Continuation application of U.S. application Ser. No. 11/329,243 filed Jan. 11, 2006. Priority is claimed based on U.S. application Ser. No. 11/329,243 filed Jan. 11, 2006, which claims the priority to Japanese Application No. 2005-005393, filed on Jan. 12, 2005, the content of which is hereby incorporated by reference into this application.

### BACKGROUND OF THE INVENTION

1. Field of the Invention

The present invention relates to a display device, for example, to a liquid crystal display device.

2. Description of the Related Art

For example, in a liquid crystal display device, there may be a case in which an organic material film is formed on a liquid-crystal-side surface of a substrate. This is because that there may be a case that each pixel of a display part is formed by patterning a conductive film, a semiconductor film, insulation films and the like by a selective etching method using a so-called photolithography technique in given patterns and stacking these films in a given order, wherein the organic material film is selected as one of the insulation films.

Since the organic material film can be formed by coating, it is possible to obtain an advantageous effect that a surface of the organic material film can be leveled and, at the same time, since the organic material film exhibits a small dielectric, it is possible to obtain advantageous effects such as the reduction of a parasitic capacitance generated between signal lines which are formed on upper and lower surfaces of the organic material layer.

In this case, the signal lines are configured to extend to the outside of a region of the display part and reach a terminal portion and, at the same time, the insulation film also extends to the outside of the region of the display part so as to protect the signal lines.

The terminal portion allows portions of the signal lines to be exposed through openings formed in the insulation film and a conductive film is formed in a state that the conductive film covers the exposed portions of the signal lines.

Such a technique is disclosed in JP-A-2000-171817 (patent document 1) and JP-A-2003-167258 (patent document 2, family is U.S. Pat. No. 6,819,389). Further, the patent document 1 discloses the constitution in which an inorganic material film is used as the insulation film which extends to the outside of the display part and the organic material film formed inside the display part does not extend to the outside of the display part. Further, the patent document 2 discloses the constitution in which the organic material film extends to the outside of a region of the display part together with other inorganic material film.

### SUMMARY OF THE INVENTION

However, the display device disclosed in the patent literature 1 is configured such that the signal lines which extend to the outside of the region of the display part are covered with only the inorganic material film having a relatively small thickness and hence, a drawback that the protection of the signal lines is insufficient has been pointed out.

That is, the inorganic material film is configured such that the inorganic material film does not extend to the outside of the region of the display part as described above and hence, when defects are present in the inorganic material film in selectively removing the inorganic material film at such portions, the signal lines are damaged.

Further, in the display device disclosed in the patent literature 2, the organic material film extends to the outside of the region of the display part and hence, the above-mentioned drawback does not arise. However, since the film thickness of the organic material film is relatively large, it is impossible to prevent a stepped portion between a signal-line exposed surface and a surface of the organic material film from being increased in the openings formed in the end portion whereby a drawback that the connection between the end portion and other electronic parts cannot ensure the reliability has been pointed out.

That is, when the connection between the end portion and other electronic parts is performed by pressure welding by way of an anisotropic conductive film, for example, there arises a large irregularity with respect to a pressure which is generated in the anisotropic conductive film and hence, a connection failure is liable to easily occur.

The invention has been made under such circumstances and it is an object of the invention to provide a display device which can ensure the sufficient protection of signal lines and can also ensure the reliability in the connection between the signal lines and other electronic parts.

To briefly explain the summary of typical inventions among inventions disclosed in this specification, they are as follows.

(1) In a display device according to the invention is, for example, signal lines formed on a substrate and an organic insulation film which covers the signal lines and is formed over an upper layer side of the substrate, a terminal portion on which a conductive film is formed in a state that the conductive film covers portions of the signal lines which are exposed through openings formed in the organic insulation film,

the organic insulation film sets a film thickness thereof at a periphery of the terminal portion smaller than the film thickness at other portions, and a surface of a small-film-thickness portion arranged in peripheries of the openings is formed into an uneven surface.

(2) A display device according to the invention is, for example, signal lines formed on display part on a liquid-crystal-side surface of a substrate and an organic insulation film which covers the signal lines and is formed over an upper layer side of the substrate, the signal lines extend to an outside of a region of the display part and, at the same time, the organic insulation film extends to the outside of the region of the display part in a state that a thickness of the organic insulation film is decreased,

a conductive film is formed in a state that the conductive film covers portions of the signal lines which are exposed through openings formed in the small-film-thickness organic insulation film, and

the organic insulation film has a surface thereof at peripheries of the openings formed into an uneven surface.

(3) The display device according to the invention is, for example, on a premise of the constitution (1) or (2), the conductive film is formed on portions of the signal lines which are exposed from the openings formed in the organic insulation film and side-wall surfaces of the openings.

(4) The display device according to the invention is, for example, on a premise of the constitution (1) or (2), the conductive film is formed in a state that the conductive film extends from portions of the signal lines exposed from the openings formed in the organic insulation film and reaches the uneven surface on the surface of the organic insulation film through the side-wall surfaces of the openings.

(5) The display device according to the invention is, for example, on a premise of the constitution (4), the conductive film is formed in a state that the conductive film extends to a position right in front of a portion of the organic insulation film where a film thickness is increased.

(6) The display device according to the invention is, for example, on a premise of any one of the constitutions (1) to (5), the signal lines have at least portions thereof which are brought into contact with the conductive film formed into an uneven surface.

(7) The display device according to the invention is, for example, on a premise of the constitution (6), concave surfaces or convex surfaces of the uneven surface intersect the running direction of the signal lines and are arranged in parallel in the running direction of the signal lines.

(8) The display device according to the invention is, for example, on a premise of the constitution (7), a gap and a width between the concave surfaces or the convex surfaces of the uneven surface are not uniform.

(9) The display device according to the invention is, for example, on a premise of the constitution (7) or (8), the concave surfaces and the convex surfaces of the uneven surface are formed in an L-shaped pattern.

(10) In a display device according to the invention is, for example, signal lines formed on a substrate and an insulation film which covers the signal lines and is formed over an upper layer side of the substrate, a terminal portion on which a conductive film is formed in a state that the conductive film covers portions of the signal lines which are exposed through openings formed in the insulation film, the signal lines have at least portions thereof which are brought into contact with the conductive film formed into an uneven surface.

(11) The display device according to the invention is, for example, on a premise of the constitution (10), concave surfaces or convex surfaces of the uneven surface intersect the running direction of the signal lines and are arranged in parallel in the running direction of the signal lines.

(12) The display device according to the invention is, for example, on a premise of the constitution (11), a gap and a width between the concave surfaces or the convex surfaces of the uneven surface are not uniform.

(13) The display device according to the invention is, for example, on a premise of the constitution (12), the concave surfaces and the convex surfaces of the uneven surface are formed in an L-shaped pattern.

Here, the invention is not limited to the above-mentioned constitution and various modifications are conceivable without departing from the technical concept of the invention.

### BRIEF DESCRIPTION OF THE DRAWINGS

FIG. 1 is a partial cross-sectional view showing one embodiment of a liquid crystal display device to which the invention is applied;

FIG. 2 is a partial cross-sectional view showing another embodiment of a liquid crystal display device to which the invention is applied;

FIG. 3 is a partial cross-sectional view showing another embodiment of a liquid crystal display device to which the invention is applied;

FIG. 4A and FIG. 4B are a plan view and a cross-sectional view showing one embodiment of a gate signal terminal of the liquid crystal display device to which the invention is applied;

FIG. 5A and FIG. 5B are a plan view and a cross-sectional view showing another embodiment of the gate signal terminal of the liquid crystal display device to which the invention is applied;

FIG. 6 is a plan view showing another embodiment of the gate signal terminal of the liquid crystal display device to which the invention is applied;

FIG. 7A and FIG. 7B are a schematic plan view of one embodiment of a liquid crystal display device to which the invention is applied and a view showing an equivalent circuit in a pixel thereof; and

FIG. 8A and FIG. 8B are a schematic plan view of another embodiment of a liquid crystal display device to which the invention is applied and a view showing an equivalent circuit in a pixel thereof.

### DESCRIPTION OF THE PREFERRED EMBODIMENTS

Hereinafter, embodiments according to the invention are explained in conjunction with attached drawings.

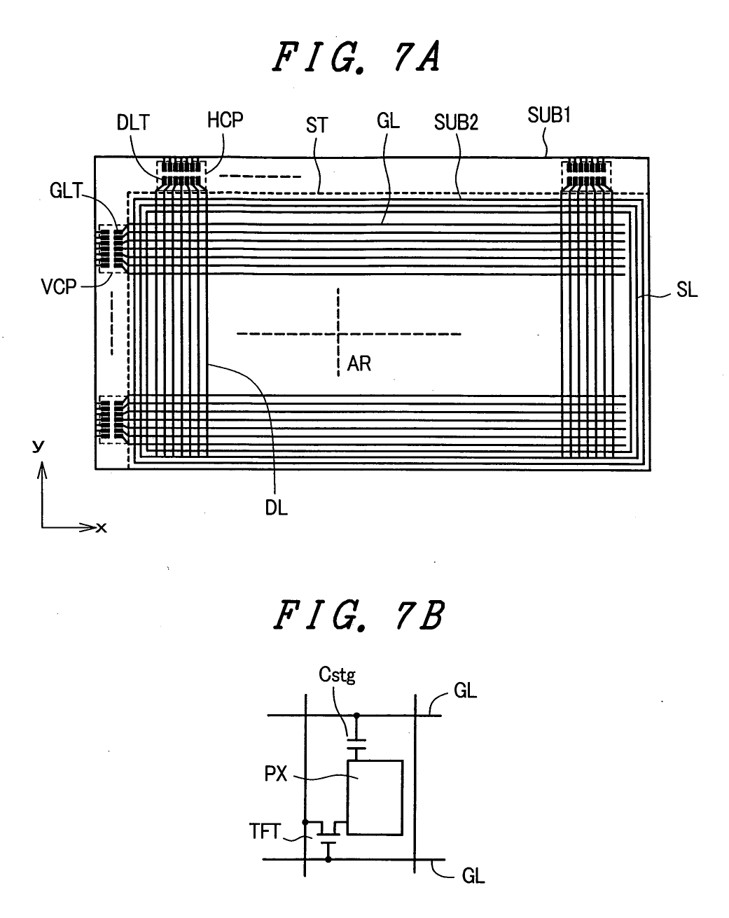

FIG. 7A is a schematic plan view showing one embodiment of a liquid crystal display device which constitutes one mode of the display device according to the invention.

A transparent substrate SUB2 is arranged to face a main surface of a transparent substrate SUB1 in an opposed manner with liquid crystal therebetween. The transparent substrate SUB1 is formed slightly larger than the transparent substrate SUB2, wherein electronic circuits (semiconductor chips VCP, HCP described later) are mounted on a portion of the main surface of the transparent substrate SUB1 which does not face the transparent substrate SUB2 in an opposed manner.

The transparent substrate SUB2 is fixed to the transparent substrate SUB1 by a sealing material SL which is formed on a periphery of the transparent substrate SUB2. The sealing material SL also has a function of sealing liquid crystal which is sandwiched between the transparent substrate SUB1 and the transparent substrate SUB2.

Further, a region which is surrounded by the sealing material SL functions as a liquid crystal display part AR, and a large number of pixels which are arranged in a matrix array are formed in the inside of the liquid crystal display part AR.

That is, in the liquid crystal display part AR formed on the main surface (liquid-crystal-side surface) of the transparent substrate SUB1, a large number of gate signal lines GL which extend in the x direction are arranged in parallel in the y direction in the drawing. One-end sides (left side in the drawing) of the gate signal lines GL get over the sealing material SL and extend to the outside of the sealing material SL and gate signal terminals GLT are formed on extended ends.

With respect to the respective gate signal lines GL, the gate signal lines GL which are arranged close to each other constitute one group, wherein in a step that gate signal lines GL in each group extend over the sealing material SL, the respective gate signal lines GL are formed in a state that the drain signal lines DL are converged together and reach the gate signal terminal GLT.

The gate signal terminals GLT of the respective group are connected to output bumps of one semiconductor chip VCP which constitutes a scanning signal drive circuit. The above-mentioned converging of the gate signal lines GL is made in a state that a spaced-apart distance between the gate signal lines GL is set larger than a spaced-apart distance between the output bumps of the semiconductor chip VCP.

Here, terminals which are connected to input terminals of the semiconductor chips VCP are formed on the surface of the transparent substrate SUB1, and signals are supplied to the terminals from a periphery of the transparent substrate SUB1.

In this case, the connection between the respective bumps of the semiconductor chip VCP and the respective terminals on the transparent substrate SUB1 is established using an anisotropic conductive film. The anisotropic conductive film is formed by scattering a large number of conductive particles in a resin film, for example.

Further, on the liquid crystal display part AR of the main surface (liquid-crystal-side surface) of the transparent substrate SUB1, a large number of drain signal lines DL which extend in the y direction and are arranged in parallel in the x direction in the drawing are formed. One-end sides (right side in the drawing) of the drain signal lines DL get over the sealing material SL and extend to the outside of the sealing material SL and drain signal terminals DLT are formed on extended ends.

With respect to the respective drain signal lines DL, the drain signal lines DL which are arranged close to each other constitute one group, wherein in a step that the drain signal lines DL in each group extend over the sealing material SL, the respective drain signal lines DL are formed in a state that the drain signal lines DL are converged together and reach the drain signal terminal DLT.

The drain signal terminals DLT of the respective group are connected to output bumps of one semiconductor chip HCP which constitutes a video signal drive circuit. The above-mentioned converging of the drain signal lines DL is made in a state that a spaced-apart distance between the drain signal lines DL is set larger than a spaced-apart distance between the output bumps of the semiconductor chip HCP.

Here, terminals which are connected to input bumps of the semiconductor chips HCP are formed on the surface of the transparent substrate SUB1, and signals are supplied to the terminals from a periphery of the transparent substrate SUB1.

In this case, the connection between the respective bumps of the semiconductor chip HCP and the respective terminals on the transparent substrate SUB1 is established using an anisotropic conductive film.

Here, the region which is surrounded by the gate signal lines GL and the drain signal lines DL is formed as a pixel region.

FIG. 7B shows the constitution in the inside of the pixel region surrounded by the gate signal lines GL which are arranged close to each other and the drain signal lines DL which are arranged close to each other as an equivalent circuit.

The pixel includes a thin film transistor TFT which is turned on in response to the supply of a signal (scanning signal) from the gate signal line GL, while a signal (video signal) from the drain signal line DL is supplied to a pixel electrode PX through the thin film transistor TFT.

An electric field corresponding to the video signal is generated between the pixel electrode PX and a counter electrode CT, and the liquid crystal is activated corresponding to a magnitude of the electric field. Here, in the drawing, a counter electrode CT is formed on another transparent substrate SUB2 side different from the transparent substrate SUB1 on which the pixel electrodes PX are formed and hence, the counter electrode CT is not shown in the drawing.

Further, out of the respective gate signal lines GL which are arranged with the pixel region therebetween, a capacitive element Cadd is formed between the gate signal line GL which is different from the gate signal line GL which drives the thin film transistor TFT of the pixel region and the pixel electrode PX, wherein the video signal supplied to the pixel electrode PX is stored by the capacitive element Cadd for a relatively long time.

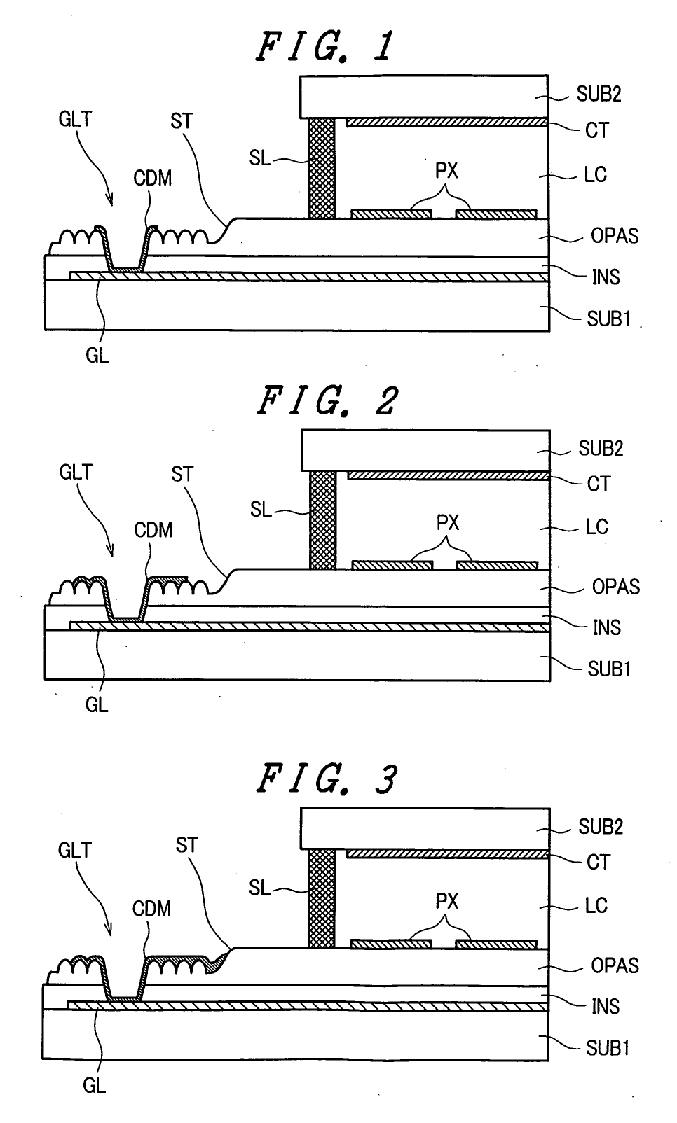

FIG. 1 is a cross-sectional view of the liquid crystal display device shown in FIG. 7 and also is a cross-sectional view along the running direction of the gate signal lines GL, wherein FIG. 1 shows a portion of the gate signal terminal GLT including a portion in the vicinity of the sealing material SL.

Although the constitution shown in FIG. 1 includes portions which are already explained in conjunction with FIG. 7, the constitution shown in FIG. 1 is explained hereinafter. First of all, the constitution includes the transparent substrate SUB1. On the main surface (liquid-crystal-side surface) of the transparent substrate SUB1, the gate signal line GL is formed, first of all.

The gate signal line GL is formed in a state that the gate signal line GL gets over the sealing material SL from the liquid crystal display part AR (portion which faces the transparent substrate SUB2 in an opposed manner) side and extends to a periphery of the transparent substrate SUB1. One end portion of this extended gate signal line GL constitutes a portion where the gate signal terminal GLP is formed.

Further, on the main surface of the transparent substrate SUB1, an insulation film INS is formed in a state that the insulation film INS also covers the gate signal line GL, wherein the insulation film INS gets over the sealing material SL and extends to an outside of the sealing material SL. The insulation film is, in a usual case, formed as a gate insulation film of the above-mentioned thin film transistor TFT (not shown in the drawing).

Further, a protective film OPAS is formed on an upper surface of the insulation film INS. The protective film OPAS is formed of a resin film, wherein the protective film OPAS is used when a surface of the insulation film INS is to be leveled by making use of an advantage that the protective film OPAS is formed by coating or the like, for example, or when there exists a demand for the reduction of a dielectric constant as an insulation film or the like. Here, below the protective film OPAS and on the upper surface of the insulation film INS, the drain signal line DL, a source electrode of the thin film transistor TFT and the like are formed.

Here, the protective film OPAS is formed in a state that the protective film OPAS gets over the sealing material SL and also extends to the outside of the sealing material SL. Further, a stepped portion ST is formed on a portion of the protective film OPAS which gets over the sealing material SL and slightly extends thus decreasing a film thickness of the protective film OPAS and such a state extends to a periphery of the transparent substrate SUB1.

The above-mentioned stepped portion ST is, as shown in FIG. 7A, formed substantially parallel to a neighboring side of the transparent substrate SUB2, wherein on a surface of the transparent substrate SUB1 which is exposed from the transparent substrate SUB2, the protective film OPAS is formed thinner than the protective film OPAS at the liquid crystal display part AR. This is because that semiconductor chips HCP, VCP are arranged in parallel in the portion.

Further, on a surface of the protective film OPAS having such a reduced film thickness, a minute unevenness is formed. Although the unevenness may be formed over a whole area of the surface of the protective film OPAS whose film thickness is reduced, it is necessary to form the unevenness on at least a periphery of a portion where the gate signal terminal GLT is formed.

The above-mentioned uneven surface formed on the protective film OPAS can be, at the time of forming a mask (photo resist) in selectively etching the portion having the smaller film thickness using the stepped portion ST as a boundary, easily formed by adopting a so-called half exposure in the selective exposure.

The gate signal terminal GLT is formed by adopting a conductive film CDM which is formed to cover a portion of the gate signal line GL which is exposed through openings formed in the protective film OPAS and the insulation film INS and side-wall surfaces of the openings as a terminal. Here, when ITO (Indium Tin Oxide), for example, is used as a material of the conductive film CDM, since the material per se is hardly oxidized, it is possible to obtain an advantageous effect that the so-called electrolytic corrosion of the gate signal line GL can be obviated.

In each pixel region above the protective film OPAS in the liquid crystal display part AR, the pixel electrode PX is formed. The pixel electrode PX is connected with the source electrode (another electrode different from the electrode which is connected to the drain signal line DL) of the thin film transistor TFT via a contact hole (not shown in the drawing) formed in the protective film OPAS. Here, the pixel electrode PX is constituted of a light-transmitting conductive film made of ITO (Indium Tin Oxide) or the like, for example.

In the liquid crystal display part AR, the transparent substrate SUB2 is fixed to the transparent substrate SUB1 with the liquid crystal LC therebetween using the sealing material SL. Further, a common electrode CT is formed in common with the respective pixels on a liquid-crystal-side surface of the transparent substrate SUB2, wherein the counter electrode CT is formed of a light transmitting conductive film made of ITO or the like, for example.

In the liquid crystal display device having such a constitution, as described above; at the portion of the protective film OPAS which gets over the sealing material SL and slightly extends from the liquid crystal display part AR, the stepped portion ST is formed, the film thickness of the protective film OPAS is reduced at the portion, and such a state extends to the periphery of the transparent substrate SUB1.

Here, the reason that the film thickness is reduced is that although the opening which exposes a portion of the gate signal line GL is formed in the protective film OPAS at such a portion and the conductive-film CDM is formed to cover at least the exposed gate signal line GL, it is possible to avoid the increase of the difference in height between the surface of the conductive film CDM and the surface of the protective film OPAS due to such reduction of the film thickness.

That is, although the gate signal terminal GLT which is formed in the above-mentioned manner is connected with an output bump of the semiconductor chip VCP via an anisotropic conductive film (not shown in the drawing), when the difference in height between the surface of the conductive film CDM and the surface of the protective film OPAS is large, the large irregularities are generated with respect to the manner of applying the pressure at the time of performing the pressure welding of the anisotropic conductive film and hence, the connection failure of the gate signal terminal GLT with the semiconductor chip VCP is liable to easily occur. By reducing the film thickness of the protective film OPAS, it is possible to prevent such a connection failure.

Further, as described above, on the surface of the portion of the protective film OPAS where the film thickness is reduced, the unevenness is formed. In this case, it is possible to obtain an advantageous effect that the gate signal terminal GLT can be reliably formed in a state that the gate signal terminal GLT is not peeled off from the protective film OPAS at a periphery thereof, for example. The reason is that although the conductive film is formed by the selective etching using a so-called photolithography technique, a photoresist which is used in such a step is firmly adhered to the protective film OPAS due to the unevenness formed on the surface of the protective film OPAS. This implies that, the photo resist is hardly peeled off from the protective film OPAS in the vicinity of the opening which corresponds to the portion where the gate signal terminal GLT is formed and hence, the reliability of the photo resist as a mask can be enhanced.

Further, FIG. 2 is a view showing another embodiment of the display device according to the invention and corresponds to FIG. 1. The constitution which makes this embodiment different from the embodiment shown in FIG. 1 lies in a conductive film CDM, wherein the conductive film CDM has a periphery thereof extended to the surface of the protective film OPAS and an extended portion is formed on the uneven surface which is formed on the surface of the protective film OPAS. In this case, the conductive film CDM can enlarge a contact region due to the uneven surface on the surface of the protective film OPAS and hence, a hermetic adhesion force of the conductive film CDM to the protective film OPAS can be enhanced. Further, the conductive film CDM having such a constitution extends over a wide range by way of the protective film OPAS and the insulation film INS and covers a periphery of the gate signal terminal GLT of the gate signal line GL and hence, the conductive film CDM has a function of a shielding film which protects the periphery of the gate signal terminal GLT from the intrusion of impurities, for example.

Still further, FIG. 3 is a view showing another embodiment of the display device according to the invention and corresponds to FIG. 2. The constitution which makes this embodiment different from the embodiment shown in FIG. 1 lies in a conductive film CDM, wherein the conductive film CDM has a periphery thereof further extended thus forming the conductive film CDM in a state that the conductive film CDM extends to the above-mentioned stepped portion ST of the protective film OPAS. In this case, it is possible to obtain an advantageous effect that the advantageous effect explained in conjunction with FIG. 2 is further increased.

Here, in all of the above-mentioned respective drawings consisting of FIG. 1 to FIG. 3, the constitution of the terminals which are connected to input bumps of the semiconductor chip VCP is omitted. However, it is needless to say that the terminals have the substantially equal constitution as the above-mentioned gate signal terminal and the above-mentioned invention is applicable to the terminals. This is because that the invention can be used for enhancing the reliability of the connection of the respective bumps of the semiconductor chip CVP.

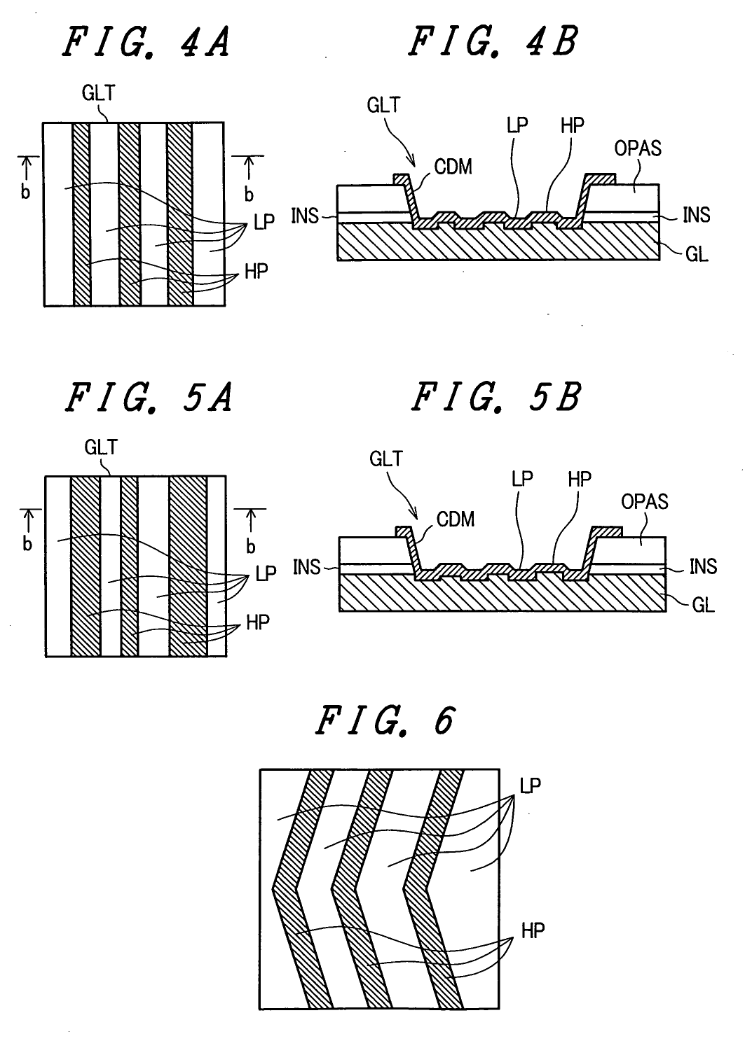

FIG. 4A and FIG. 4B are views showing another embodiment which applies a further improvement to the above-mentioned gate signal terminal GLT, wherein FIG. 4A is a plan view and FIG. 4B is a cross-sectional view taken along a line b-b in FIG. 4A.

In FIG. 4A and FIG. 4B, at a portion of the conductive film CDM which is brought into contact with the gate signal line GL, for example, a plurality of convex surface portions HP which extend in the direction perpendicular to the running direction of the gate signal line GL are arranged at a substantially equal interval with widths thereof set substantially equal. As a result, between the respective convex surface portions HP, a concave surface portion LP is formed thus providing the constitution in which the convex surface portions HP and the concave surface portions LP are alternately arranged. That is, a contact surface between the gate signal line GL and the conductive film CDM is corrugated in the running direction of the gate signal line GL and hence, the surface area is extremely increased compared to the contact surface which has neither the convex surface portions HP nor the concave surface portions LP.

Accordingly, the adhesive property of the conductive film CDM to the gate signal line GL can be enhanced thus achieving the stabilization and the reduction of resistance of the electrical connection.

Here, in forming the gate signal lines GL by patterning, by applying a so-called half exposure to the convex surface portions HP or the concave surface portions LP, the convex surface portions HP or the concave surface portions LP can be easily formed.

FIG. 5 is a view showing another embodiment of the gate signal terminal GLT and corresponds to FIG. 4.

The constitution which makes this embodiment different from the embodiment shown in FIG. 4 lies in that, for example, the convex surface portions HP which are arranged in parallel in a state that the gaps thereof are made different from each other in the juxtaposed direction and, at the same time, the widths thereof are also changed.

In forming the convex surface portions HP or the concave surface portions LP by the half exposure in the above-mentioned manner, a photo mask which is applied to such portions adopts a pattern which regularly repeats a light shielding portion and a light transmitting portion. However, when the gaps and the widths of these light shielding portions and the light transmitting portions are equal, the interference of light is generated and hence, the uneven surface having a desired shape cannot be formed. Accordingly, in this embodiment, the gate signal terminal GLT is formed to prevent the gaps and the widths of the light shielding portions and the light transmitting portions from becoming uniform. By adopting such a constitution, as a result, the convex surface portions HP or the concave surface portions LP are formed in a pattern shown in FIG. 5.

Further, FIG. 6 is a view showing another embodiment of the gate signal terminal GLT and corresponds to FIG. 4A or FIG. 5A.

The constitution which makes this embodiment different from the embodiment shown in FIG. 4A or FIG. 5A lies in that convex surface portions HP or concave surface portions LP which are formed while intersecting the running direction of the gate signal lines GL have portions thereof at an imaginary center axis of the gate signal line GL bent thus forming an L shape. Also in this case, it is possible to ensure the reliability with respect to the adhesive property of the gate signal line GL and the conductive film CDM.

Here, in the above-mentioned embodiments, the explanation has been made with respect to the constitution in which the liquid crystal is driven by the pair of electrodes which are arranged while sandwiching the liquid crystal therebetween in the layer thickness direction. However, it is needless to say that the invention is substantially equally applicable to a display device having the constitution in which the liquid crystal is driven by a pair of electrodes which are arranged in parallel in the spreading direction of the liquid crystal.

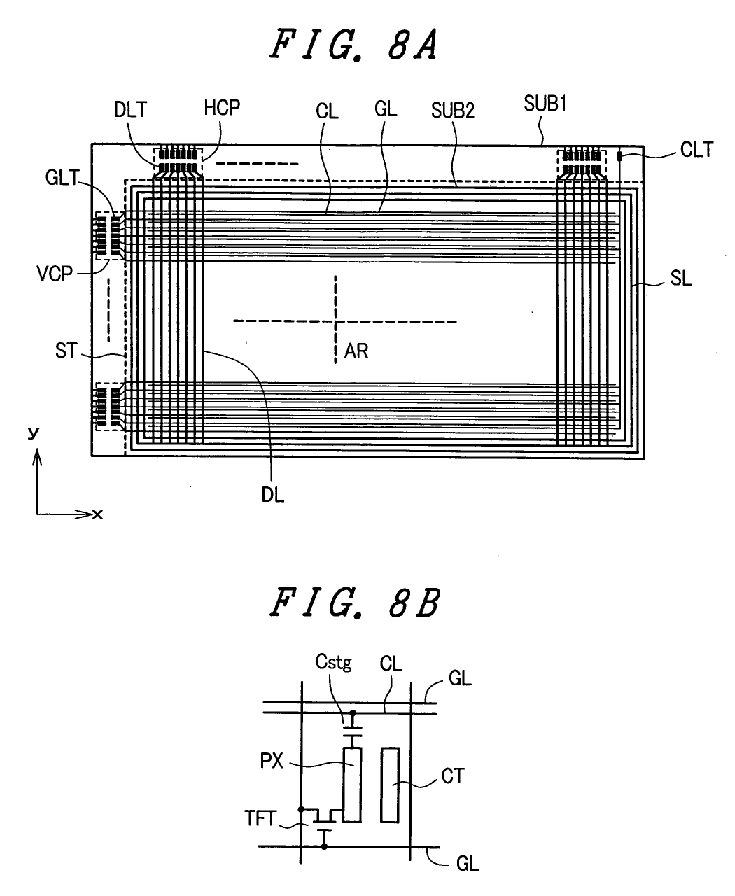

FIG. 8A is a plan view of the display device having the constitution of the latter display device and corresponds to FIG. 7A.

The constitution which makes the display device shown in FIG. 8A different from the display device shown in FIG. 7A lies in that, first of all, a counter voltage signal line CL is formed on a liquid-crystal-side surface of the transparent substrate SUB1, and a counter voltage signal which is supplied through the counter voltage signal line CL is supplied to counter electrodes CT of respective pixels. The counter voltage signal line CL is formed in common with the respective pixels which are arranged in parallel in the x direction in the drawing and, at the same time, the counter voltage signal line CL is connected with other counter voltage signal lines CL in common at a right end in the drawing, for example, wherein a connection signal line gets over a sealing material SL and is connected with a counter voltage signal terminal CLT.

The counter electrode CT is, as shown in FIG. 8B, formed in parallel with a pixel electrode PX. Although not shown in FIG. 8B which shows an equivalent circuit, the counter electrode CT and the pixel electrode PX are respectively constituted of a plurality of electrodes in an actual constitution, and in each pixel region of the transparent substrate SUB1, these electrodes are alternately arranged thus forming a so-called comb-teeth pattern.

Further, it is also possible to adopt the constitution in which the counter electrode CT (or the pixel electrode PX) is formed over at least a whole area of the pixel region, and a plurality of pixel electrodes PX (or counter electrodes CT) which are formed in a stripe shape are arranged to be overlapped to the counter electrode CT (or the pixel electrode PX) by way of an insulation film.

A capacitive element Cstg is formed between the pixel electrode PX and the counter voltage signal line CL, wherein the capacitive element Cstg has the substantially same function as the above-mentioned capacitive element Cadd.

Here, the above-mentioned counter voltage signal line CL which is formed on a surface of the transparent substrate SUB1 may be formed on the same layer as a gate signal line GL, for example, and a terminal of the counter voltage signal line CL has the substantially same constitution as a gate signal terminal GLT and hence, the above-mentioned embodiment can be directly applied as it is also with respect to the terminal.

Further, in the above-mentioned respective embodiments, the explanation has been made with respect to the gate signal terminal GLT. However, the above-mentioned constitution is also applicable to the drain signal terminal DLT in the substantially same manner.

This is because that the drain signal terminal DLT has the substantially equal constitution as the gate signal terminal GLT except for that the drain signal line DL is arranged between an insulation film INS and a protective film OPAS, the drain signal terminal DLT of the drain signal line DL is constituted such that a conductive film is formed to cover a portion of the drain signal line DL which is exposed by an opening formed in the protective film OPAS, and the insulation film INS is positioned above the gate signal line GL with respect to the gate signal terminal GLT.

Further, in the above-mentioned respective embodiments, the explanation has been made by taking the liquid crystal display device as the example. However, it is needless to say that the invention is applicable to an organic EL display device, for example.

This is because that, the organic EL display device also uses signal lines which have the same functions as the gate signal line GL and the drain signal line DL and hence, there may be a case that an organic material film is used as an insulation film.

Further, the organic EL display device also includes a power source supply signal line which supplies a power source to organic EL elements of respective pixels besides the above-mentioned signal lines. It is needless to say that the invention is applicable to a terminal of the power source supply signal line.

The above-mentioned respective embodiments may be used in a single form respectively or in combination. This is because that it is possible to obtain the advantages of respective embodiments individually or synergistically.

What is claimed is:

1. A display device comprising:
signal lines formed on a substrate;
an insulation film which covers the signal lines and is formed over an upper layer side of the substrate;
a terminal portion on which a conductive film is formed in a state that the conductive film covers portions of the signal lines which are exposed through openings formed in the insulation film;
wherein the signal lines have at least portions thereof which are brought into contact with the conductive film formed into an uneven surface.

2. A display device according to claim 1, wherein concave surfaces or convex surfaces of the uneven surface intersect the running direction of the signal lines and are arranged in parallel in the running direction.

3. A display device according to claim 2, wherein a gap and a width between the concave surfaces or the convex surfaces of the uneven surface are not uniform.

4. A display device according to claim 3, wherein the concave surfaces and the convex surfaces of the uneven surface are formed in a “ku” wording shape pattern in Japanese, like [symbol] .
